(19) United States
(12) Patent Application Publication
(10) Pub. No.: US 2021/0304644 A1
(43) Pub. Date: Sep. 30, 2021

(54) Weatherproof Outdoor Digital Display

(71) Applicant: Sealoc Texas, Inc., McKinney, TX (US)

(72) Inventor: Richard Franklin WEBSTER, McKinney, TX (US)

(21) Appl. No.: 17/007,724

(22) Filed: Aug. 31, 2020

Related U.S. Application Data
(60) Provisional application No. 63/002,907, filed on Mar. 31, 2020.

(51) Int. Cl. G09F 9/35; H05K 5/02; H05K 5/00; G02B 5/20; G02B 1/11; G02B 1/14; G09F 27/00

(52) U.S. Cl. CPC G09F 9/35; H05K 5/0213; H05K 5/0017; G02B 5/208; G09F 2027/001; G02B 1/14; H05K 5/0226; G09F 27/005; G02B 1/11

(57) ABSTRACT

A weatherproof sign having a weatherproof case with an openable front panel attached to a rear section and a display screen integrated within the openable front panel with a bezel-less protective transparent layer disposed on an exterior side of the display screen so as to form an enclosed air gap between the display screen and the protective transparent layer and a plurality of electronic components having weatherproofed coating in communication with the controller to control operation of the sign.

### CLAIM TO PRIORITY

This application claims the benefit of pending U.S. provisional application number 63/002,907, filed Mar. 31, 2020, the entirety of which is incorporated herein by reference.

### TECHNICAL FIELD

This disclosure relates generally to the field of outdoor display devices to provide information such as quick service restaurant menu items. It is particularly related to an outdoor digital display comprising a weatherproof display screen and easily accessible electronic components facilitating rapid, on-site repair and/or replacement. The weatherproof outdoor display herein described is self-contained and weatherproof without encasing the display in a separate weatherproof cover, container or other device. The presently described outdoor display device according to the embodiments described herein achieves both IP65 weatherproof certification, and IK10 impact resistant certification, as described below.

### BRIEF DESCRIPTION OF THE DRAWINGS

The novel features believed characteristic of the invention are set forth in the appended claims. The invention itself, however, as well as a preferred mode of use, further objectives and advantages thereof, will be best understood by reference to the following detailed description of illustrative embodiments when read in conjunction with the accompanying drawings and photographs, wherein:

FIG. 1 depicts a perspective view of a weatherproof outdoor digital display according to an embodiment of the invention.

FIG. 2 depicts a side view of a weatherproof outdoor digital display according to an embodiment of the invention.

FIG. 3 depicts a perspective view of a weatherproof outdoor digital display in an open position according to an embodiment of the invention.

FIG. 4 depicts a side view of a weatherproof outdoor digital display in an open position according to an embodiment of the invention.

FIG. 5 depicts a back view of a weatherproof outdoor digital display in an open position according to an embodiment of the invention.

FIG. 6 depicts a front view of a weatherproof outdoor digital display in an open position according to an embodiment of the invention.

### DETAILED DESCRIPTION OF THE EMBODIMENTS

The detailed description set forth below is intended as a description of the present embodiments of the invention and is not intended to represent the only form in which the present invention may be constructed or utilized. The description sets forth the functions and sequences of steps for constructing and operating, the invention. It is to be understood, however, that the same or equivalent functions and sequences may be accomplished by different embodiments and that they are also intended to be encompassed within the scope of the invention.

Several embodiments of Applicant's invention will now be described with reference to the drawings. Unless otherwise noted, like elements will be identified by identical numbers throughout all figures. The invention illustratively disclosed herein suitably may be practiced in the absence of any element which is not specifically disclosed herein.

The presently described invention relates to an outdoor digital display (e.g. monitor/TV) for use in the Quick Serve Restaurant (QSR) industry. The presently described outdoor digital display is contemplated for use largely within the “drive thru” industry, which includes fast-food restaurants, coffee shops, traditional restaurants which utilize drive-thru windows, pharmacies and more. Other contexts for the various embodiments of the outdoor digital display are contemplated, and other contexts for use are considered within scope of this application.

The presently described QSR outdoor digital displays have been purpose-built to solve for inadequate designs from other manufacturers where a traditional display is placed inside a weatherproof housing or “box”. Such attempted solutions have various shortcomings and disadvantages. Such problems associated with existing displays include overheating, inability to service a broken display, insufficient illumination, isotropic blackout conditions, increased costs to the purchaser, increased needs for frequent servicing, and others.

The outdoor digital display of the present invention provides an affordable, yet very high quality solution for the QSR industry by creating a fully weatherproof display that can be placed virtually anywhere in the world regardless of extreme cold or hot weather conditions, dry or tropical and humid environments (e.g. northern Canada in extreme cold environments, Phoenix, AZ in extremely hot and dry environments, tropical locations where it is both hot and humid, coastal environments where it is hot & cold and has salt-air conditions, and so forth). The outdoor digital display described herein resolves a number of problems within the industry, but also adds features and benefits.

The presently described outdoor digital display is a high-bright display emitting approximately 3,500 nits (cd/m2) of brightness through its display screen, yet it is configured to emit 5,000 nits (cd/m²) or greater. The outdoor digital display utilizes an ambient light sensor that allows it to automatically increase or decrease the brightness up to 100 percent of its brightness, or down to 20 percent of its brightness. This allows the unit to run more efficiently, increase the lifespan of the product, and for the viewer it ensures that the brightness is at an optimal viewing level (not too bright during dark hours). Additional benefits to the ambient light sensor feature are that it allows the outdoor digital display to run more efficiently which saves electrical energy costs, and prolongs the life of the outdoor digital display. The outdoor digital display, according to the various embodiments is modular allowing for optional components to be built into the outdoor display, such as cameras, speakers, microphones or motion sensors.

A plurality of cameras can be built into the outdoor display to serve multiple purposes such as providing a restaurant order taker the ability to see who is placing the order (and vice versa through the display), and to view and read license plates. Reading license plates may allow the drive through restaurant to use historical information as to what that customer purchased previously and then provide suggested items for purchase. The speakers and microphones would allow for the drive through restaurant order taker to listen to and speak to the drive through customer. Motion sensors can be added to the outdoor display either internally or externally. These motion sensors can send a signal to the outdoor display to turn it on when it senses motion and then further allow the outdoor display to turn off when no motion is sensed thus saving the drive through restaurant money from reduced electrical usage.

The outdoor digital display, according to the various embodiments is serviceable in the field by qualified technicians, has an all-aluminum (or steel) body, a protective (impact resistant) glass screen and is designed to withstand elements such as rain, snow, heat, extreme cold, hail, and even hurricane winds. The outdoor digital display described herein allows 24 hours per day, 7 days per week, 365 days per year operation and provides many years of trouble-free service to its consumer. In one embodiment, the display screen includes a bezel-less design whereby the protective glass is an insert to the metal body, further enhancing protection, while giving providing a sleek and clean, progressive look. The product features Class A grade and Class A+grade components such as an industrial Liquid Crystal Display (LCD) panels sourced from top-tier manufacturers (e.g. LG, Samsung, etc.), highest-of-quality Light Emitting Diode (LED) backlight units, double-ball bearing brushless fans, and more. Moreover, the display utilizes a unique “air gap” technology that places a space between the protective glass and the LCD panel, which allows for additional cooling capabilities, further impact resistance, and lower cost to the end user. The outdoor digital display also houses a “media bay” built into the back of the display which allows the end user to a) place components safely inside a weatherproof, internal box (or bay), and b) route any power or signal cables out of the media bay, while at the same time providing the ability, in one embodiment, to remove the media bay cover with two simple toolless, thumbscrew fasteners. Other suitable fasteners can be used in other embodiments.

The outdoor digital display presently described allows an authorized/qualified repair technician simple and improved access to the internal components of the display to quickly and efficiently repair the unit, on-site.

The QSR outdoor digital display presently described allows a repair technician to easily and efficiently open the display with common tools, and a supplied key. In one embodiment, once unlocked, the front half of the display pivots down on hinges to approximately a 90-degree angle. This grants the technician unfettered access to a multitude of components, including power supplies, cooling fans, video boards, LED backlight units, wiring harnesses, and the like that could possibly fail over the life of the display. This access enables fast and efficient replacement of any failed components, which in turn enables getting the display back in service in minutes. In other such outdoor displays, the display must be removed from its mounted solution, and a replacement unit installed at a later time.

In some embodiments, the presently described outdoor digital display comprises one or more hinges at the bottom, and steel chains covered with a non-conductive sleeve to limit how far the display will open. In other embodiments, the outdoor digital display comprises gas-pressurized shocks that allow the display to open on its own. This eliminates the need to physically remove the display and order and replace the display unit back in the display box, frame or carcass.

The presently described outdoor digital display allow multiple components within the body of the display housing, to be easily replaced. This includes one or more power supplies within the body of the display. In some embodiments, the outdoor digital display includes multiple power supplies that take 120-volt or 240-volt input power, and then supply both AC and DC power to the totality of subcomponents within the display itself. These power supplies are designed to be easily replaced either in the field, or within a repair center.

In some embodiments an LED backlighting system is highly modular in nature. Typically, if a single LED light suffers a failure, the entire LED backlight module (or entire display) is rendered useless and the entire display must be replaced or repaired at a specialized repair facility, typically in a clean-room environment. In the presently described outdoor digital display, however, a single strip of LED backlights can be replaced in the field, within minutes, and with common hand tools.

Similarly, in the embodiments of the presently described outdoor digital display all supporting printed circuit boards (PCBs) within the display can be easily removed and replaced as needed. These include, but are not limited to, the video processing and input PCB, jumper PCB, relay PCB boards, T-CON PCB boards, and the like.

In some embodiments, the presently described outdoor digital display comprises two types of cooling fans: a) fans that provide general cooling to the entire unit, and b) fans that provide both cooling and anti-fogging solutions that are tied to the “air gap” technology. Both types of these fans are designed to be easily removed and replaced either in the field or at an authorized service center.

In addition, the embodiments of the outdoor digital display comprise one or more air filters that are user-serviceable in nature. In a stock or standard configuration, the air filters are designed to filter out standard, ambient impurities such as dust and dirt. In an upgraded fashion, the air filters can be upgraded to a Gore-Tex filter which will filter out smaller impurities such as salt-air, sulfuric acid and much more. Both of which are designed to be easily replaced by the user with common hand tools, washed with clean water, dried, and then placed back into the display.

In some embodiments, the outdoor digital can be fitted with marine-grade, weatherproof speakers to provide audio output for the end user. These speakers are also designed to be easily replaced both in the field, or at an authorized repair facility. These marine-grade, weatherproof speakers are positioned in such a way that it provides a seal between the perforated exterior and the interior of the outdoor display, so as not to interfere with the IP65 ingress protection rating. In general, the other components (with the exception of the LCD panel, the body of the display itself, and the protective glass) can all be replaced easily within the field or an authorized service center with common tools. This includes, but is not limited to, timing controllers, LED drivers, relay boards, counter boards, jumper boards, microphones, cameras and the like.

The presently described outdoor digital display can be mounted in a number of different ways that are unique for this product, as described below. The presently described outdoor digital display is completely weatherproof and vandal resistant, and does not need to be placed inside a separate protective enclosure that would otherwise require additional cost to the purchaser, and additional cooling to cope with the ambient and display-generated heat. As such, the presently described outdoor digital display can be mounted in at least two ways.

In one embodiment, a podium mount is used to mount and secure the outdoor digital display. The podium style mount allows for mounting of one or multiple QSR displays side-by-side in a tight-pattern configuration. This mounting configuration provides easy access to on-site repairs, as described above. In addition, easy installation and removal of the displays without the need for specialized tools or equipment is provided. Also, better, more accurate alignment of the displays to create an even, aligned set of monitors for a clean aesthetic look is achieved. Podium mounting also eliminates the need for an outer box to create a weatherproof solution. The podium mount results in a smaller footprint, lower cost, and requiring less space for the user.

In another embodiment, the outdoor digital display can be wall mounted much like a TV or display, utilizing VESA-standard mounting systems.

The presently described outdoor digital display includes an air-gap. A layer of protective safety glass is placed at the front of the display. The body and structure of the display then creates an approximately 4-6 mm gap between the protective safety glass and the liquid crystal display (LCD) panel behind it. A series of air manifolds are built into the body of the overall display that pushes clean, cool, filtered air between the safety glass and the LCD panel, thusly helping to cool the display, and at the same time provide an “air barrier” between the protective safety glass and the sensitive and fragile LCD panel. An added benefit is further protection of the display's LCD from isotropic blackout which is induced by high heat situations caused by a buildup of ultraviolet and infrared radiation emitted by the sun.

The presently described outdoor digital display further comprises Isotropic Blackout Prevention Technology displays that prevent an instance of isotropic blackout on the display. Isotropic Blackout is a condition where both Infrared (IR) and Ultraviolet (UV) radiation emitted from the sun, enters a display and causes all or part of the LCD panel to overheat and “black out”. This condition can be temporary or permanent depending upon many environment factors. The long term effect is that a portion, or all sections of the LCD panel, become faded or permanently “blacked out” and viewing capabilities are diminished. An example is seen at a gas station pump where it is very difficult or even impossible to read the display. This is caused by continued exposure to the sun's IR and UV radiation. The presently described outdoor digital display filters out approximately ninety nine percent of the IR and UV radiation before it reaches the LCD panel, largely preventing Isotropic Blackout conditions. This is achieved by altering the “cut” (how the exterior, protective glass is made), and by adding lamination to the interior portion of the front-facing glass that filters out the IR and UV radiation.

In addition to filtering out IR and UV radiation, a specialized film is placed on the inside portion of the protective screen to reduce the effects of reflective light. This film reduces two types of reflection: a) the reflection that is produced from the light emitting from the LCD panel and bouncing between the panel the outer safety glass, and b) the light coming from the outside environment bouncing against the outside portion of the safety glass. The end result is that in virtually all lighting conditions, the user perceives a much lower level of reflection.

In addition to the anti-UV, and anti-IR lamination that is applied, a specialized lamination is applied to the inside of the protective glass that reduces any chance of glass fragmentation or “shards” should the glass become broken by a heavy blow. This is similar to how automotive windshields are made and has a similar effect.

In another embodiment, an extreme cold weather heater can be installed in the outdoor digital display herein described. This heater in one embodiment comprises an internal radiant heater that enables the outdoor digital display QSR display in its entirety to function in extremely cold weather conditions (e.g. below freezing temperatures that would otherwise render a non-heated outdoor display inoperative).

In another embodiment, the outdoor digital display as described includes hardware and software to permit the user to remotely monitor and manage multiple components and functions of the display. The remote management system can provide device management capabilities of up to 255 displays on a single network subnet, which includes functions such as remote power on/power off, remote display input selection, remote control of volume (including “muting” the audio output), and remote management of the brightness of the display. The remote monitoring system can provide device management capabilities of up to 255 displays on a single network subnet, which includes functions such as the internal temperature of the display (displayed in either Celsius or Fahrenheit), the internal humidity of the LCD, the presence of signal from an input device (e.g. a content management system, a standard HDMI input source, etc.), key voltages of critical components thusly verifying activation and operation (includes, but not limited to LED backlight, cooling fans, video boards, internal audio amplifier, etc.) and/or the presence and functionality of any electrically-controlled accessories such as video cameras, “gas sensors”, etc. Both the remote management and remote monitoring solution is designed to be modular and upgradeable in nature, thusly giving the unit added features as needed for future design changes/enhancements.

Remote Management gives the end user, either via a desktop application, or a mobile application, the ability to remotely and discreetly turn on or off a single display within a network, change inputs (e.g. HDMI1, HDMI2, etc.) or revise other operational parameters of the outdoor digital display unit.

Remote Monitoring gives the end user the ability, either via a desktop application, or a mobile application, to remotely monitor a single display for conditions such as ambient temperature, humidity, and sub-component functionality.

In another embodiment, the outdoor digital display is treated with anti-graffiti coating. The outdoor digital display is treated with a paint/power coat solution that allows the end user to remove paint, market or pen graffiti with a simple water/soap solution.

In addition, the outdoor digital display's internal components are conformally coated with a special solution that help alleviate the destructive and corrosive nature of salt-air, or other corrosive environmental conditions that would otherwise prematurely corrode and destroy the sensitive electronics within the display.

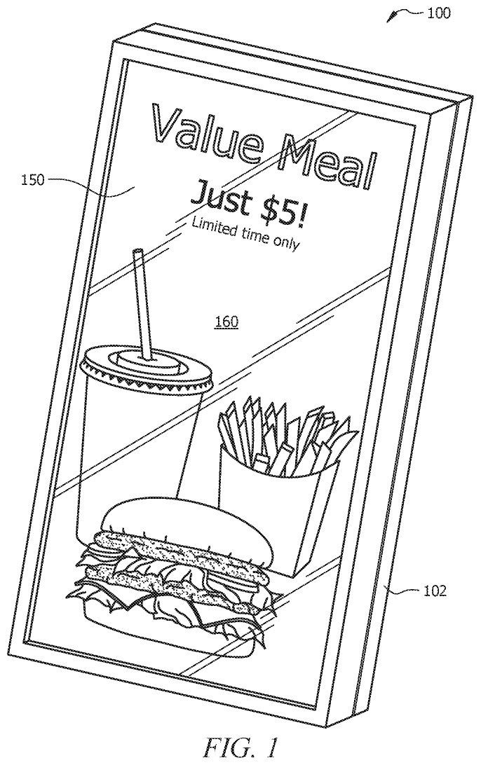

FIG. 1 depicts a perspective view of a weatherproof outdoor digital display according to an embodiment of the invention. In FIG. 1, outdoor digital display 100 comprises two main portions. The first portion is display section 150 and the second is rear display body 102 embody the two most major components of the outdoor display. Display section 150 includes a display screen 160 through which digital media can be displayed. Display screen 160 is comprised of the exterior IK10-rated protective glass, the “air gap” as previously described, the LCD panel, the LED backlighting system, and all supporting mechanical framework to secure display screen 160 together. Outdoor digital display 100 pivots downward to approximately 90 degrees to permit access to its various electronic components for component-level repair, as will be discussed in detail. Rear display body 102 is comprised of the exterior rear portion of the body, the VESA mounting screws, a media bay to store various external components, removable handles, and interiorly houses various printed circuit boards, electrical wires and wire bundles, power supplies, a video board and the like. Display screen 160, and rear display body 102 however, are not individually designed to achieve a weatherproof solution or achieve IP65 ratings as described below. Instead, outdoor digital display 100 achieves its weatherproof capability by virtue of the display screen 160 and the rear display body 102 being in a closed and locked position for normal operation.

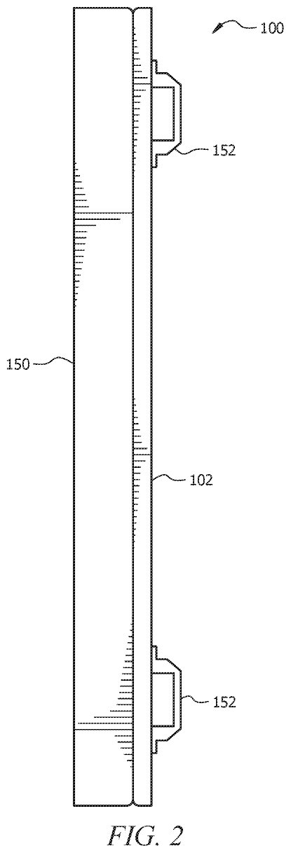

FIG. 2 depicts a side view of a weatherproof outdoor digital display according to an embodiment of the invention. As shown, outdoor digital display 100 is relatively thin in design. In this figure, outdoor digital display 100 is in a closed position, as it would be seen when in use, to display digital media. Display section 150 abuts rear display body 102 when outdoor digital display 100 is in this closed position. Extending from rear display body 102 are a plurality of handles 152 to provide ease in transporting, installing and maintaining outdoor digital display 100. These plurality of handles 152 can be easily removed with common hand tools, while the rear display body 102, includes the threaded inserts (to retain handles 152) in a manner that still allows the outdoor digital display 100 to retain its weatherproof and IP65 certification protection—in other words, the threaded inserts do not allow particulates, dust, water or other foreign bodies to enter inside the outdoor digital display 100.

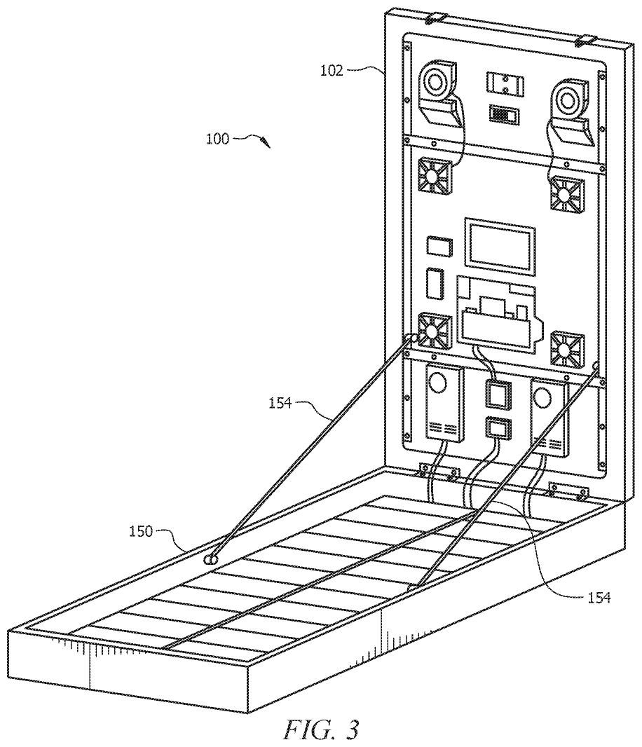

FIG. 3 depicts a perspective view of a weatherproof outdoor digital display in an open position according to an embodiment of the invention. As shown in FIG. 3, outdoor digital display 100 placed in the open position results in display section 150 being lowered to a substantially perpendicular position in relation to rear display body 102. This is achieved by one or more hinges at the lower interface of display section 150 and rear display body 102. The extent of lowering of display section 150 when outdoor digital display 100 is open is achieved by one or more chains 154. In various embodiments, chains 154 are made of galvanized or stainless steel and covered with a non-conductive sleeve or coated with non-conductive material. The length of chains 154 limit how far the display will open as without one or more chains, the weight of display section 150 will result in display section 150 moving past perpendicular in relation to rear display body 102, in turn resulting in partial or total breakage of the hinges. If a hinge is damaged, effective closure of outdoor digital display 100 will be lost and the product will require repair. However, like other modular components, the hinges can be easily replaced with common hand tools.

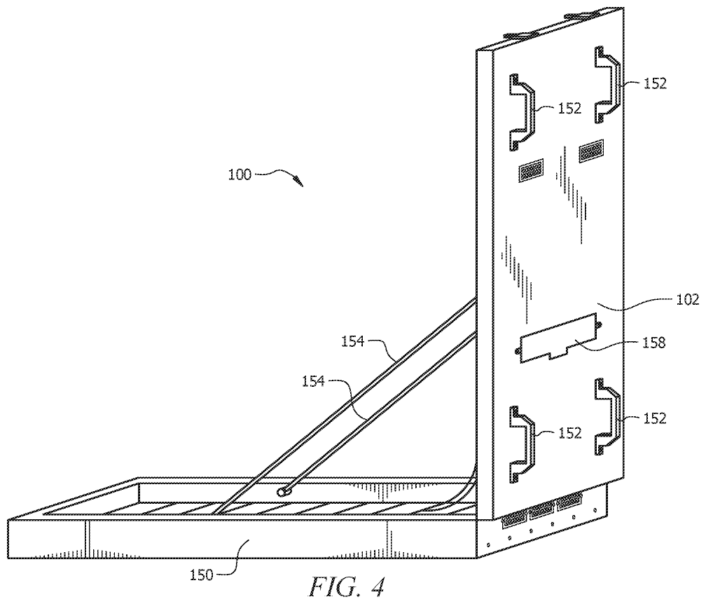

FIG. 4 depicts a side view of a weatherproof outdoor digital display in an open position according to an embodiment of the invention. As shown in FIG. 4, outdoor digital display 100 is in a full open position as display section 150 is in the substantially perpendicular position in relation to rear display body 102. This position is achieved by chains 154 limiting the extent to which display section 150 can be lowered, as discussed. As shown, handles 152 extend from the exterior of media bay 102.

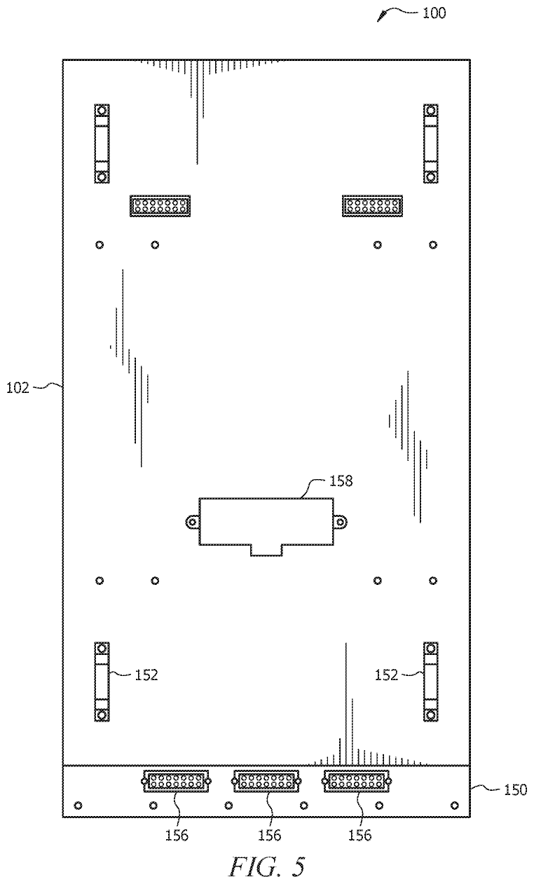

FIG. 5 depicts a back view of a weatherproof outdoor digital display in an open position according to an embodiment of the invention. In FIG. 5, once again outdoor digital display 100 is in the open position, with display section 150 in a substantially perpendicular position in relation to rear display body 102. The exterior of rear display body 102 is shown, again with a plurality of handles 152 disposed at optimal locations. Disposed on a lower face of the rear display body 102, is media bay 158 that houses a) receptacles for digital inputs such as HDMI cables, RS232 communication cables, network cable, etc., b) the power cord, and c) to safely and securely house other devices. Media bay 158 includes a removable cover providing a weatherproof seal to prevent entry of water or other liquids, while at the same time allows for cables and connectors to be routed through the bottom. Media bay 158 cover incorporates a weatherproof, soft seal that is captured between media bay 158 cover and the rear display body 102, which is then secured by two thumbscrews which require no tools to remove or install.

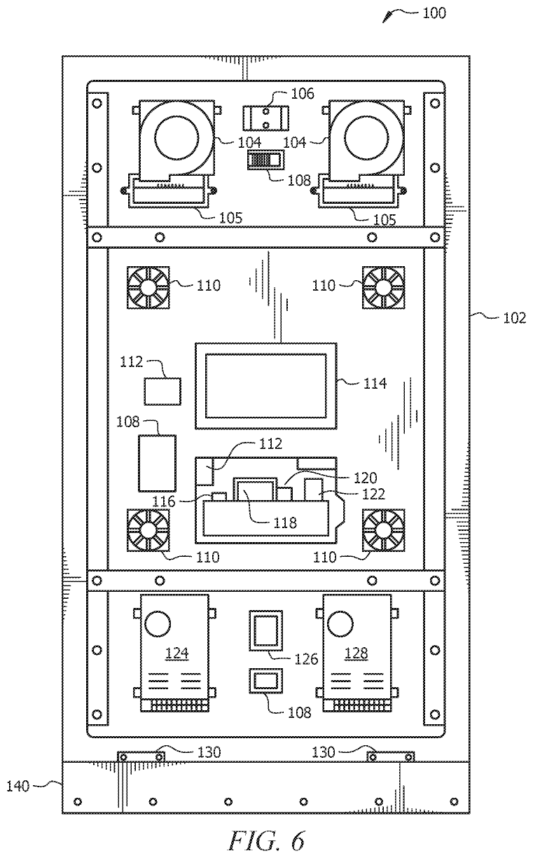

FIG. 6 depicts a front view of the inside of rear display body 102, in an open position according to an embodiment of the invention. In this figure, the various internal components of outdoor digital display 100 are provided. The locations of the various internal components depicted in FIG. 6 is but just one of several possible arrangements and are by no means limiting. In addition, the components shown are not exhaustive as other components can be included but not shown in the figure.

In an upper region of the interior of outdoor digital display 100 within media bay 102 reside one or more clearing fans 104. These fans provide air circulation and cooling to outdoor digital display 100. A series of air manifolds are built into the body of the overall display that pushes clean, cool, filtered air between the safety glass and the LCD panel of display 160, thus, helping to cool display 160, and at the same time provide an “air barrier” between the protective safety glass and the sensitive and fragile LCD panel of display 160. Manifolds 105 disposed beneath clearing fans 104. Manifolds 150 are positioned and constructed to prevent water or other liquids be sprayed or poured onto or into them from entering outdoor digital display 100, or any internal components. It is designed similarly to that of a “P” trap underneath a kitchen or bathroom sink.

Between clearing fans 104 are fail safe and operating thermostats 106 and jumper and relay board 108. Thermostats 106 control cooling of the interior of outdoor digital display 100 by virtue of controlling operation of fans 104. In addition, fail safe thermostats cause various electrical components of outdoor digital display 100 to temporarily power down when excessive heat is sensed in the event that fans 104 can't meet cooling requirements in extreme heat in order to prevent component damage. Below thermostat 106 is jumper and relay 108.

Within the interior of rear display body 102 and below fans 104 are a plurality of LED cooling fans 110. These fans are located in close proximity to the video and display components, and when in a closed position, located in close proximity to the LED backlight assemblies, of outdoor digital display 100 to provide direct cooling of LEDs and other components that drive the digital display features of outdoor digital display 100. Within this section of rear display body 102 are another jumper relay 108 as well as a pair of jumper boards 112. A first power supply 114 supplying power to power input board 116 are also situated within this section of the interior of rear display body 102. A video graphics board 118, USB slot 120 and RS232 input port 122 are co-located in this area. In proximity to the bottom of the interior of rear display body 102 of outdoor digital display 100 are another jumper relay 108 a second power supply 124, a third power supply 128 and timing controller board 126. A pair of hinges 130 connect the bottom of the exterior of rear display body 102 to lower side 140 of display section 150. This arrangement of electronic components serves to deliver data for display on display screen 160 of the outdoor digital display 100. The ability to open and close outdoor digital display 100 for maintenance and repair without compromising the weatherproof capability of display screen 160 dramatically enhances the life span and in service time of outdoor digital display 100.

The various embodiments of outdoor digital display 100 achieve both IP65 and IK10 protection from various elements and impacts. With respect to its ingress protection (governed by IEC standard 60529), outdoor digital display 100 achieves IP65 certification. The “6” in “IP65” means outdoor digital display does not allow for ingress of dust, whereas the “5” in “IP65” ensures that the outdoor digital display can withstand water projected by a nozzle (6.3 mm (0.25 in)) against enclosure from any direction with no harmful effects. Outdoor digital display 100 utilizes a protective glass and body construction that allows it to achieve an IK10 certification (governed by the international standard IEC 62262). IK 10 impact protection allows for up to 20 joules of impact without causing any damage that would render the unit inoperable. This is roughly equivalent to 5 kilograms of mass being dropped 400 millimeters from the impacted surface.

While the invention has been particularly shown and described with reference to a preferred embodiment, it will be understood by those skilled in the art that various changes in form and detail can be made therein without departing from the spirit and scope of the invention.

What is claimed is:

1. A weatherproof sign, comprising:
a weatherproof case having an openable front panel attached to a rear section;
a display screen integrated within the openable front panel;
a bezel-less protective transparent layer disposed on an exterior side of the display screen so as to form an enclosed air gap between the display screen and the protective transparent layer;
a shatterproof glass laminate disposed on the bezel-less protective transparent layer;
an anti-reflective laminate;
an anti-graffiti laminate disposed on the exterior of the bezel-less protective transparent layer;
an ambient light sensor in communication with a controller to control brightness of one or more light sources disposed within the weatherproof case;
a plurality of electronic components in communication with the controller to control operation of the sign;
a media bay disposed on the exterior side of the rear section;
at least one communication cable disposed in the media bay for communication with a remote display management platform;
a power supply disposed within the weatherproof case;
a clearing fan disposed within the weatherproof case;
a plurality of manifolds disposed below the clearing fan; and
a limiting connector disposed between a bottom section of the front panel and a bottom section of the rear section to limit the extent to which the front panel opens,
wherein the plurality of electronic components comprise a weatherproofing coating.

2. The weatherproof sign of claim 1, further comprising a camera.

3. The weatherproof sign of claim 1, further comprising at least one speaker.

4. The weatherproof sign of claim 1, further comprising at least one microphone.

5. The weatherproof sign of claim 1, further comprising a motion sensor.

6. The weatherproof sign of claim 1, wherein the display screen comprises a liquid crystal display.

7. The weatherproof sign of claim 1, wherein the one or more light sources comprises a light emitting diode.

8. The weatherproof sign of claim 1, further comprising an infrared light and ultraviolet light restricting laminate layer disposed on an exterior side of the protective layer.

9. The weatherproof sign of claim 1, further comprising an infrared light and ultraviolet light restricting laminate layer disposed on an outer side of the display screen.

10. The weatherproof sign of claim 1, wherein the anti-reflective laminate disposed on an outer side of the display screen.

11. The weatherproof sign of claim 1, wherein the anti-reflective laminate disposed on an outer side of the display screen.

12. The weatherproof sign of claim 1, wherein the plurality of electronic components are disposed within the interior of the rear section.

13. The weatherproof sign of claim 1, wherein the limiting limits movement of at least one hinge disposed between the openable front panel and the rear section.

14. The weatherproof sign of claim 1, wherein the motion sensor communicates with the controller to illuminate the display screen upon detecting motion.
